(19) United States
(12) Patent Application Publication
(10) Pub. No.: US 2016/0268289 A1
(43) Pub. Date: Sep. 15, 2016

(54) INTEGRATED CIRCUIT DEVICE AND METHOD FOR MANUFACTURING THE SAME

(71) Applicant: Kabushiki Kaisha Toshiba, Minato-ku (JP)

(72) Inventor: Kotaro NODA, Yokkaichi (JP)

(73) Assignee: Kabushiki Kaisha Toshiba, Minato-ku (JP)

(21) Appl. No.: 14/656,927

(22) Filed: Mar. 13, 2015

(51) Int. Cl. H01L 27/115; H01L 23/535

(52) U.S. Cl. CPC H01L 27/11582; H01L 27/11556; H01L 23/535

(57) ABSTRACT

According to one embodiment, an integrated circuit device includes a pillar extending in a first direction and a plug that is connected to an end part of the pillar on a longitudinal direction side. A contact face between the pillar and the plug including a portion inclined relative to a plane perpendicular to the first direction.

### CROSS-REFERENCE TO RELATED APPLICATIONS

This application is based upon and claims the benefit of priority from U.S. Provisional Patent Application 62/047,181, filed on Sep. 8, 2014; the entire contents of which are incorporated herein by reference.

### FIELD

Embodiments described herein relate generally to a integrated circuit device and a method for manufacturing the same.

### BACKGROUND

Conventionally, high integration of an integrated circuit device has been promoted, and however, the method of increasing an integration degree by enhancing of the lithography and etching technology is approaching to a limit, and a stacked-type integrated circuit device has been proposed. In the stacked-type integrated circuit device, a stacked body in which a word line and an interlayer insulating film are stacked alternately and a silicon pillar penetrating the stacked body are provided. On the upper part of the silicon pillar, an electrode is provided and is connected with a contact plug.

### BRIEF DESCRIPTION OF THE DRAWINGS

FIG. 1 is a sectional view illustrating an integrated circuit device according to a first embodiment;

FIGS. 2 to 19 are sectional views illustrating the method for manufacturing the integrated circuit device according to the first embodiment;

FIG. 20 is a sectional view illustrating an integrated circuit device according to a variation of the first embodiment;

FIG. 21 is a sectional view illustrating an integrated circuit device according to a second embodiment;

FIGS. 22 to 26 are sectional views illustrating the method for manufacturing the integrated circuit device according to the second embodiment;

FIG. 27 is a sectional view illustrating an integrated circuit device according to a third embodiment;

FIGS. 28 to 30 are sectional views illustrating the method for manufacturing the integrated circuit device according to the third embodiment;

FIGS. 31 to 34 are sectional views illustrating a method for manufacturing an integrated circuit device according to a forth embodiment; and

FIGS. 35 and 36 are sectional views illustrating a method for manufacturing an integrated circuit device according to a variation of the forth embodiment.

### DETAILED DESCRIPTION

According to one embodiment, an integrated circuit device includes a pillar extending in a first direction and a plug that is connected to an end part of the pillar on a longitudinal direction side. A contact face between the pillar and the plug including a portion inclined relative to a plane perpendicular to the first direction.

According to one embodiment, a method for manufacturing an integrated circuit device includes forming a stacked body on a substrate by stacking an insulating film and an electrode film alternately. The method for manufacturing an integrated circuit device also includes forming a slit penetrating the stacked body in the stacking direction to form an insulating member by embedding an insulating material into the slit. The method for manufacturing an integrated circuit device also includes removing an upper part of the insulating member and the stacked body to form a first wave shape on a face including an upper face of the insulating member and an upper face of the stacked body. The method for manufacturing an integrated circuit device also includes forming a memory hole penetrating the stacked body in the stacking direction and depositing a semiconductor material in the memory hole to form a semiconductor member. The method for manufacturing an integrated circuit device also includes depositing a conductive material on the semiconductor member, the insulating member and the stacked body to form a conductive member, and forming a second wave shape reflecting the first wave shape on an upper face of the conductive member. The method for manufacturing an integrated circuit device also includes forming an electrode by removing the conductive member except in the memory hole to form a semiconductor pillar composed of the semiconductor member and the electrode, and forming a third wave shape reflecting the second wave shape on a face including an upper face of the insulating member, an upper face of the semiconductor pillar and an upper face of the stacked body. The semiconductor pillar upper face including a part of the third wave shape.

Embodiments of the invention will now be described with reference to the drawings.

### First Embodiment

First, a first embodiment will be described.

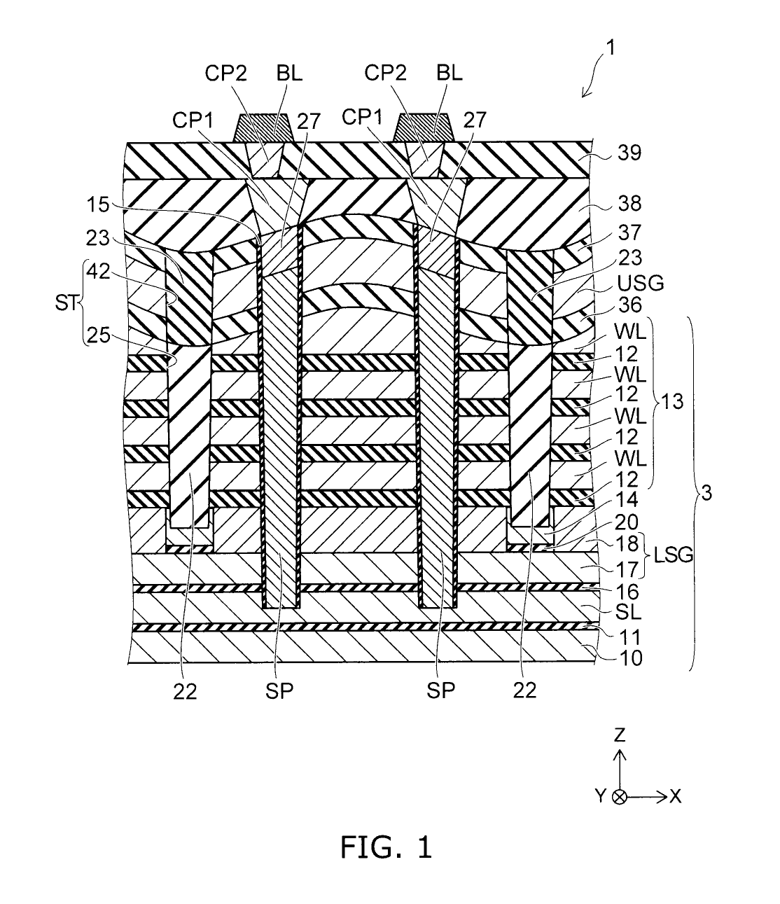

FIG. 1 is a sectional view illustrating an integrated circuit device according to the embodiment.

The integrated circuit device according to the embodiment is a stacked-type integrated circuit device.

As shown in FIG. 1, in an integrated circuit device 1 according to the embodiment, a silicon substrate 10 is provided, and an insulating film 11 is provided on the silicon substrate 10.

Hereinafter, in the specification, an XYZ orthogonal coordinate system is adopted for convenience of description. That is, in FIG. 1, two directions which are parallel to a contact face between the silicon substrate 10 and the insulating film 11 and orthogonal to each other are assumed to be “X-direction” and “Y-direction”. In addition, an upward direction perpendicular to a contact face between the silicon substrate 10 and the insulating film 11 is assumed to be “Z-direction”.

On the insulating film 11 of the integrated circuit device 1, along the Z-direction from the bottom, provided are a source line SL, an interlayer insulating film 16, a lower selection gate electrode LSG, a stacked body 13, an interlayer insulating film 36, an upper selection gate electrode USG, an interlayer insulating film 37, an interlayer insulating film 38, an interlayer insulating film 39 and a bit line BL. The lower selection gate electrode LSG is composed of an electrode film 17 and an electrode film 18. The stacked body 13 is formed with an insulating film 12 and a word line WL stacked alternately.

On a part of a lower layer portion in the electrode film 18, a barrier metal film 20 extending in the Y-direction is provided so as to be in contact with an upper face of the electrode film 17. On an upper face of the barrier metal film 20, a stopper member 14 extending in the Y-direction in the same way is provided.

On the stopper member 14, a lower part 25 of a slit ST for separating the word line WL is formed so as to penetrate the stacked body 13 in the Z-direction. On the lower part 25 of the slit ST, an upper part 42 of the slit ST is formed so as to penetrate the stacked body from the interlayer insulating film 37 to the interlayer insulating film 36 in the Z-direction. In the lower part 25 of the slit ST, an insulating member 22 with an insulating material embedded is formed. An insulating material is embedded in the upper part 42 of the slit ST to form an insulating member 23. The insulating member 22 and the insulating member 23 extend in the Y-direction.

On the insulating film 11, a memory hole MH is formed lateral to the insulating member 22 so as to penetrate the stacked body from the interlayer insulating film 37 to an upper layer portion of the source line SL in the Z-direction, and a memory film 15 is provided on an inner surface of the memory hole MH. On the side nearer to the central axis than the memory film 15, a silicon pillar SP is provided. The memory film 15 is formed with a block insulating film, a charge film and a tunnel insulating film stacked in order from the outside. Thereby, a memory cell is formed in a crossing portion between the word line WL and the silicon pillar SP.

An electrode 27 is provided on an upper part of the silicon pillar SP. On an upper face of the electrode 27, a contact plug CP1 embedded in the interlayer insulating film 38 is provided, and is made to be contiguous and connected to the electrode 27. A contact face between the electrode 27 and the contact plug CP1 is inclined relative to an XY plane, that is, a plane perpendicular to the central axis of the electrode 27 and the contact plug CP1. A contact area between the electrode 27 and the contact plug CP1 is large as compared with a case where the contact face comes in contact horizontally. The electrode 27 is formed of a conductive material such as silicon (Si) with an impurity doped, a metal silicide such as a nickel-silicon (NiSi) or a metal such as tungsten (W), for example. The contact plug CP1 is formed of, e.g., tungsten.

On an upper face of the contact plug CP1, a contact plug CP2 embedded in the interlayer insulating film 39 is provided, and is connected with the contact plug CP1. On the contact plug CP2, the bit line BL is provided, and is connected with the contact plug CP2.

The insulating film 11, the interlayer insulating film 12, the interlayer insulating film 16 and the interlayer insulating film 36 to the interlayer insulating film 39 are formed of, e.g., a silicon oxide (SiO). The source line SL, the lower selection gate electrode LSG, the word line WL and the upper selection gate electrode USG are formed of, e.g., silicon (Si). The stopper member 14 is formed of, e.g., tantalum (Ta). The contact plug CP2 and the bit line BL are formed of, e.g., tungsten.

Next, a method for manufacturing the integrated circuit device according to the embodiment will be described.

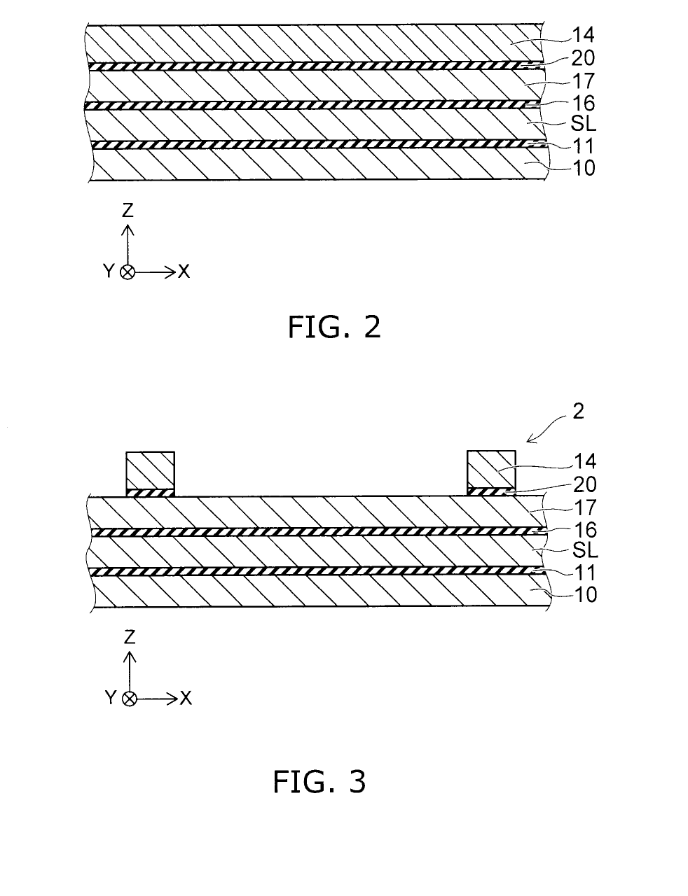

FIGS. 2 to 19 are sectional views illustrating the method for manufacturing the integrated circuit device according to the embodiment.

First, as shown in FIG. 2, the insulating film 11 composed of a silicon oxide (SiO) is formed on the silicon substrate 10 with, e.g., an HDP-CVD (High Density Plasma chemical vapor deposition) method, and the source line SL, the interlayer insulating film 16, the electrode film 17, the barrier metal film 20 and the stopper member 14 are made to be stacked thereon in this order.

Next, as shown in FIG. 3, by specifying a region where the stopper member 14 is formed with lithography and by applying dry etching thereto, the stopper member 14 and the barrier metal film 20 are selectively removed to form a structure 2.

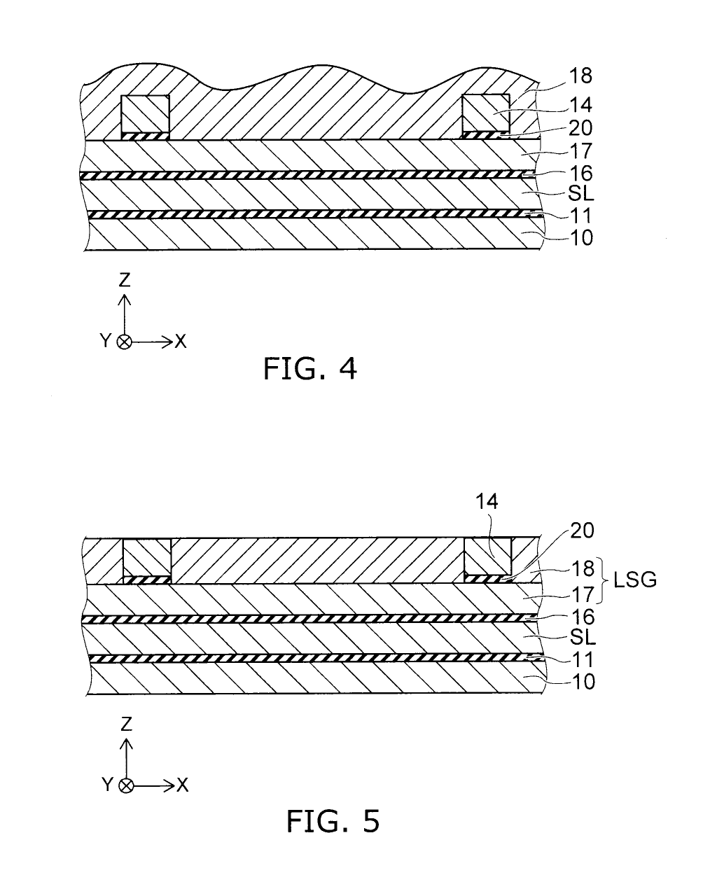

Next, as shown in FIG. 4, the electrode film 18 is formed on the structure 2.

Next, as shown in FIG. 5, an upper part of the electrode film 18 is removed with CMP (Chemical Mechanical Polishing) and RIE (Reactive Ion Etching), and flattening treatment is carried out to expose the electrode film 18 and the stopper member 14. The electrode film 17 and the electrode film 18 together constitute the lower selection gate electrode LSG.

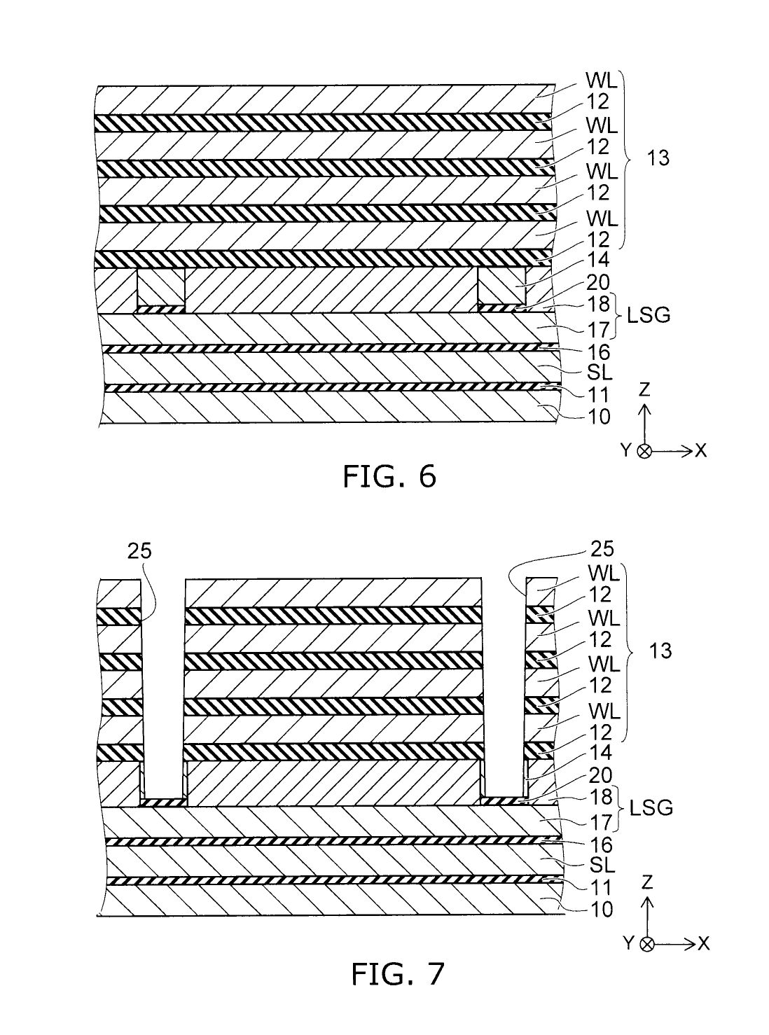

Next, as shown in FIG. 6, the interlayer insulating film 12 and the word line WL are stacked alternately to form the stacked body 13 on an upper face of the stopper member 14 and the lower selection gate electrode LSG.

Next, as shown in FIG. 7, by specifying a region where the lower part 25 of the slit ST is formed with, e.g., the lithography and by applying etching thereto, the stacked body 13 is selectively removed to form the lower part 25 of the slit ST penetrating this stacked body 13 in the Z-direction and extending in the Y-direction. Thereby, the word line WL is separated in the X-direction.

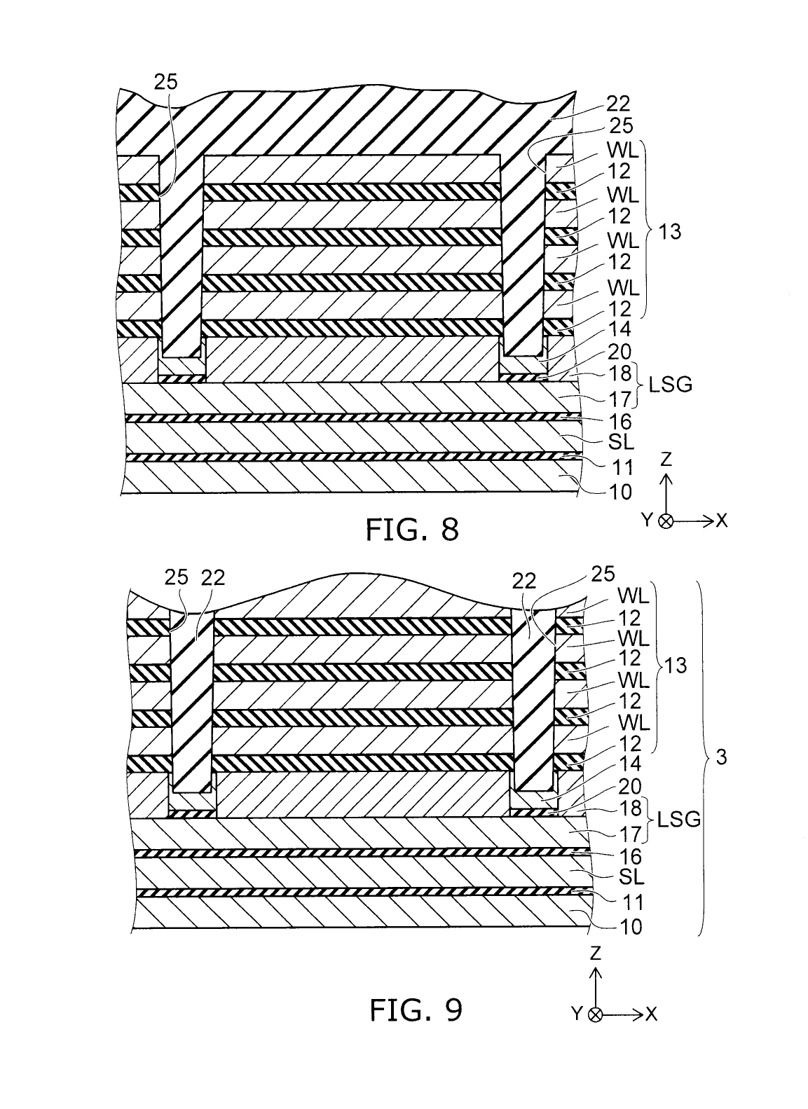

Next, as shown in FIG. 8, an insulating material is made to be deposited. The insulating material is deposited on the stacked body 13 and also enters into the lower part 25 of the slit ST. The insulating material embedded in the lower part 25 forms the insulating member 22.

Next, as shown in FIG. 9, overall etching is applied on a condition that an etching rate of the silicon oxide becomes higher than an etching rate of silicon. Thereby, a portion deposited on an upper face of the stacked body 13 in the insulating material is removed. At this time, by applying over etching, an upper layer portion of the word line WL constituting a top layer of the stacked body 13 and an upper part of the insulating member 22 are also removed. However, since an etching rate of the silicon oxide is higher than an etching rate of silicon in this etching, the insulating member 22 is preferentially etched rather than the word line WL. As the result, on a face including an upper face of the insulating member 22 and an upper face of the word line WL, a wave shape where an upper face of the insulating member 22 becomes relatively lower and an upper face of the word line WL becomes relatively higher appears. An intermediate structure fabricated until this process is assumed to be a structure 3.

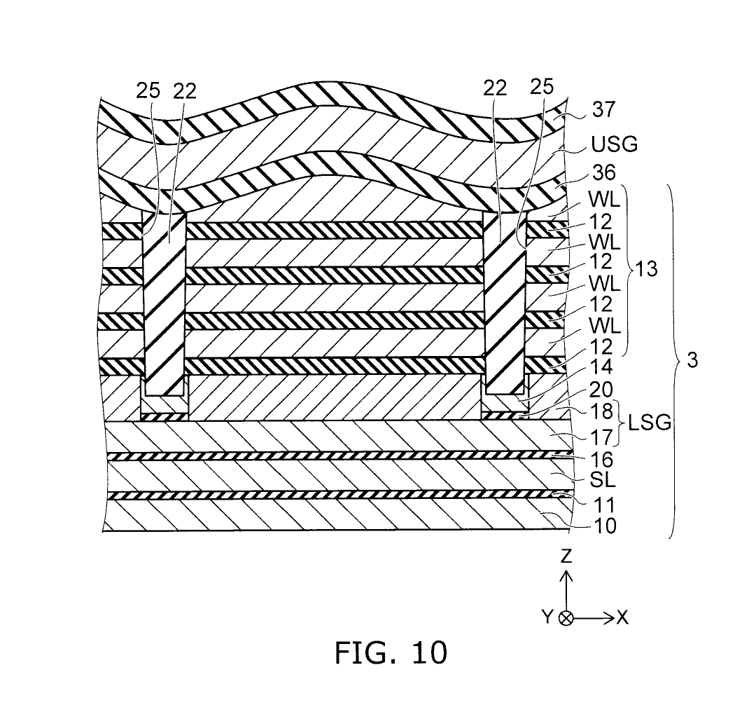

Next, as shown in FIG. 10, the interlayer insulating film 36, the upper selection gate electrode USG and the interlayer insulating film 37 are made to be stacked in this order on the structure 3. At this time, a shape of the interlayer insulating film 36, the upper selection gate electrode USG and the interlayer insulating film 37 becomes a wave shape reflecting a shape of the foundation (refer to FIG. 9).

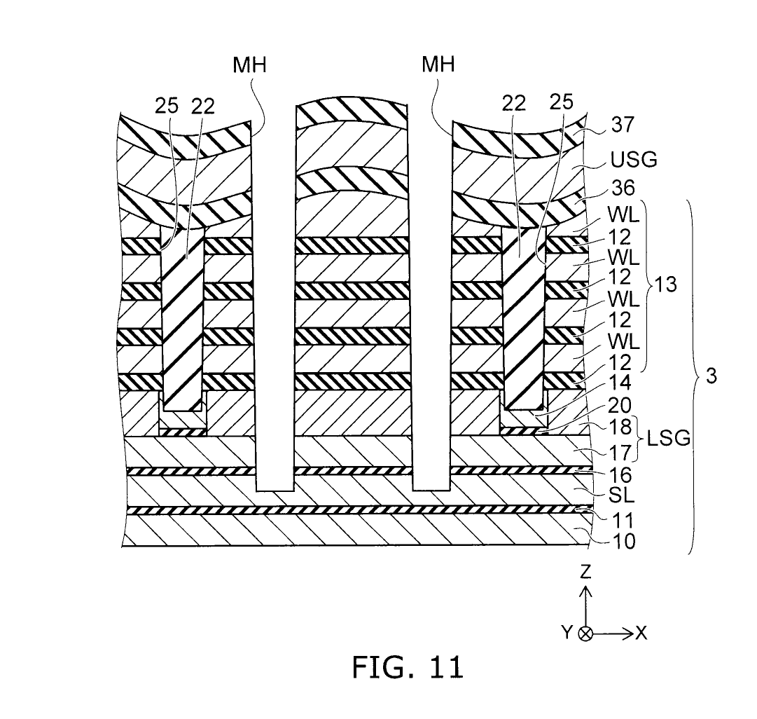

Next, as shown in FIG. 11, by specifying a region where the memory hole MH is formed with the lithography and by applying etching thereto, the stacked body from the interlayer insulating film 37 to an upper layer portion of the source line SL is selectively removed to form the memory hole MH penetrating this stacked body in the Z-direction.

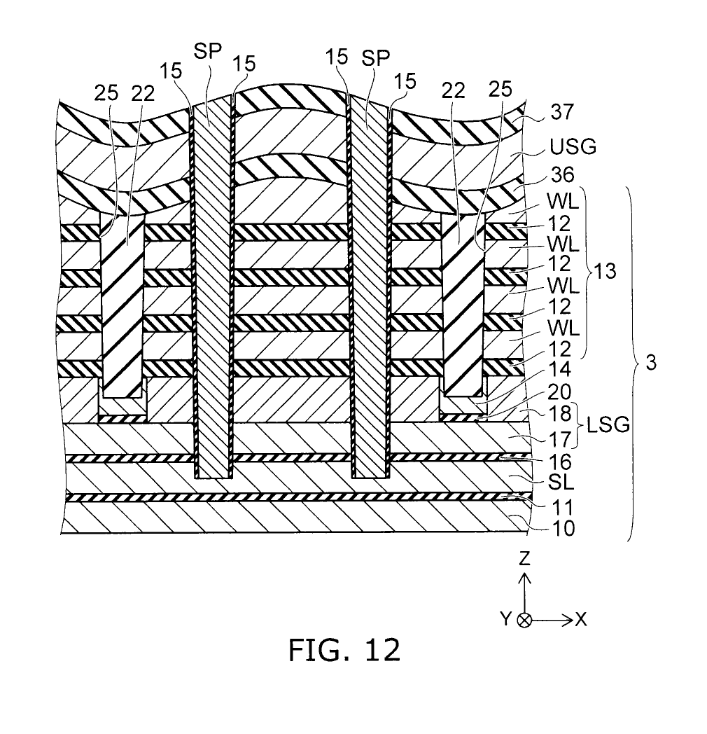

Next, as shown in FIG. 12, the block insulating film, the charge film and the tunnel insulating film are made to be formed in this order on a side surface of the memory hole MH to form the memory film 15. Thereafter, the memory film 15 is removed from a bottom face of the memory hole MH by applying anisotropic etching such as RIE. Thereafter, the inside of the memory hole MH is filled up with, e.g., silicon to form the silicon pillar SP. A lower end of the silicon pillar SP is connected to the source line SL.

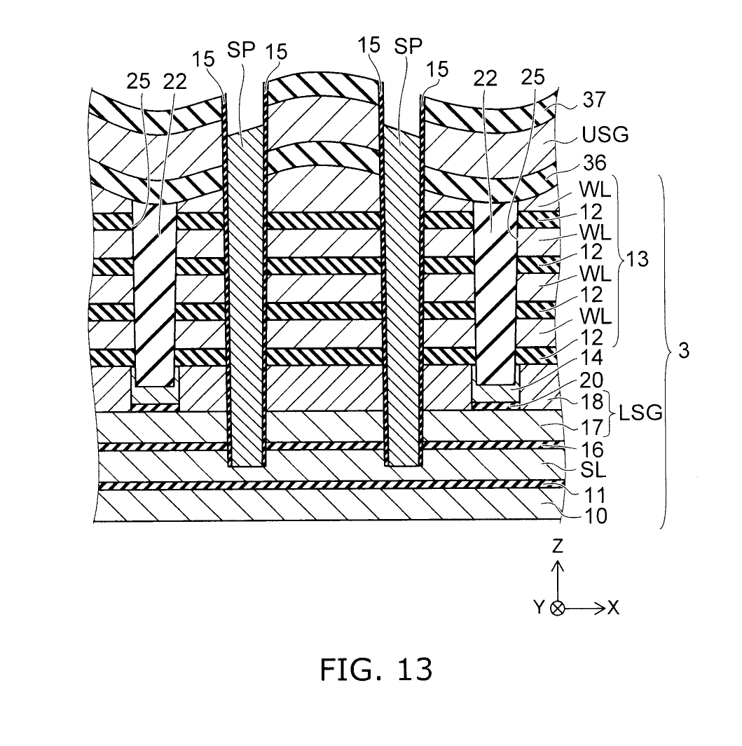

Next, as shown in FIG. 13, an upper part of the silicon pillar SP is removed by applying etchback. At this time, a shape of an upper face of the silicon pillar SP becomes an inclined shape.

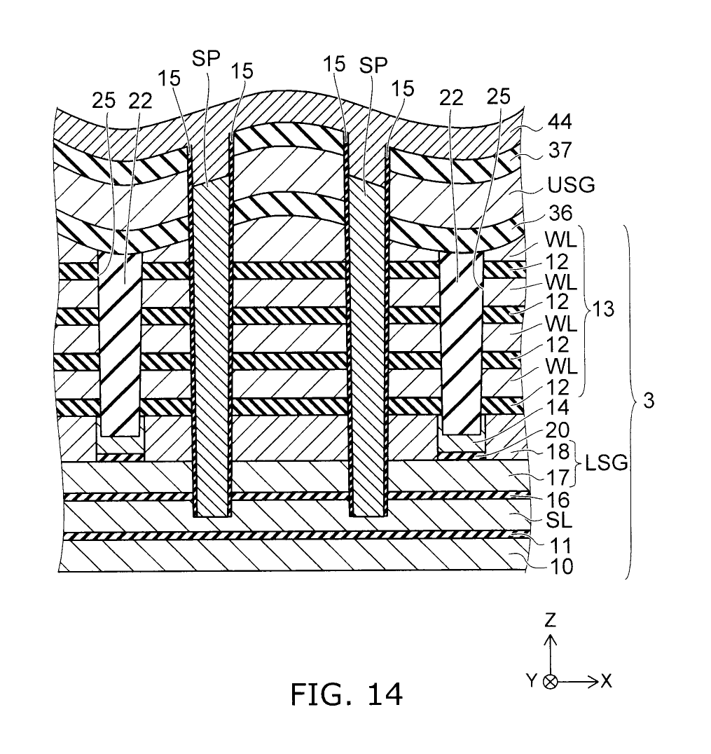

Next, as shown in FIG. 14, a conductive member 44 is formed by depositing a conductive material including, e.g., silicon on the silicon pillar SP and the interlayer insulating film 37. At this time, a shape of an upper face of the conductive member 44 becomes a wave shape by being influenced by a shape of an upper face of the interlayer insulating film 37.

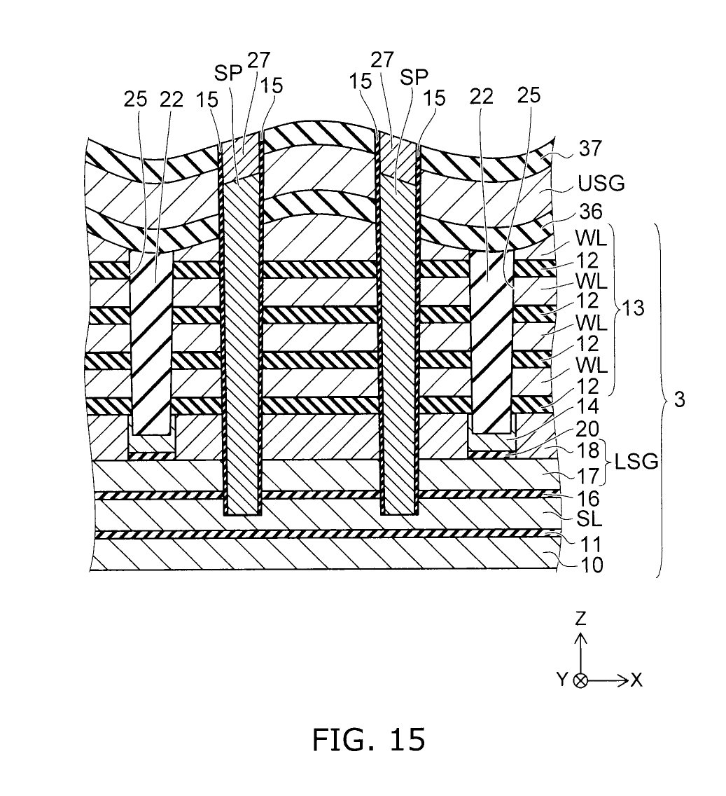

Next, as shown in FIG. 15, other portions except the portion embedded in the memory hole MH of the conductive member 44 are removed by applying etchback on the whole surface. The portion remaining in the memory hole MH is made to be the electrode 27. A shape of an upper face of the electrode 27 becomes an inclined shape in which a direction where the nearest slit ST exists becomes a valley side. Thereby, an area of an exposed surface of the electrode 27 becomes large as compared with a case where the exposed surface of the electrode 27 is a plane perpendicular to the central axis of the electrode 27 and the silicon pillar SR

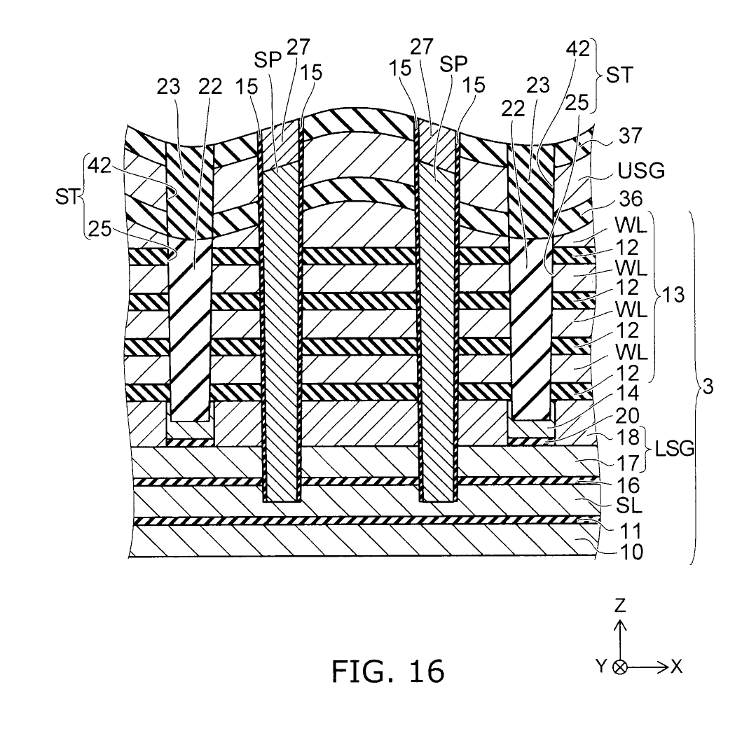

Next, as shown in FIG. 16, by specifying a region where the upper part 42 of the slit ST is formed with the lithography and by applying etching thereto, the stacked body from the interlayer insulating film 37 to the interlayer insulating film 36 is selectively removed to form the upper part 42 of the slit ST penetrating this stacked body in the Z-direction and extending in the Y-direction in a region right above the lower part 25 of the slit ST. Thereafter, an insulating material composed of, e.g., a silicon nitride is embedded in the upper part 42 of the slit to form the insulating member 23.

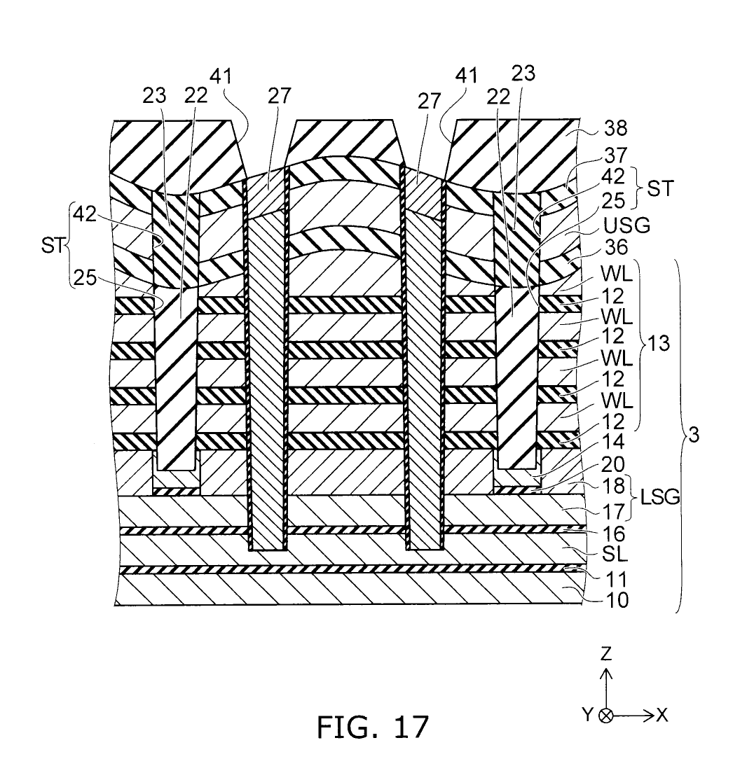

Next, as shown in FIG. 17, after the interlayer insulating film 38 is formed on the electrode 27 and the interlayer insulating film 37, a contact hole 41 is formed by applying the lithography and etching.

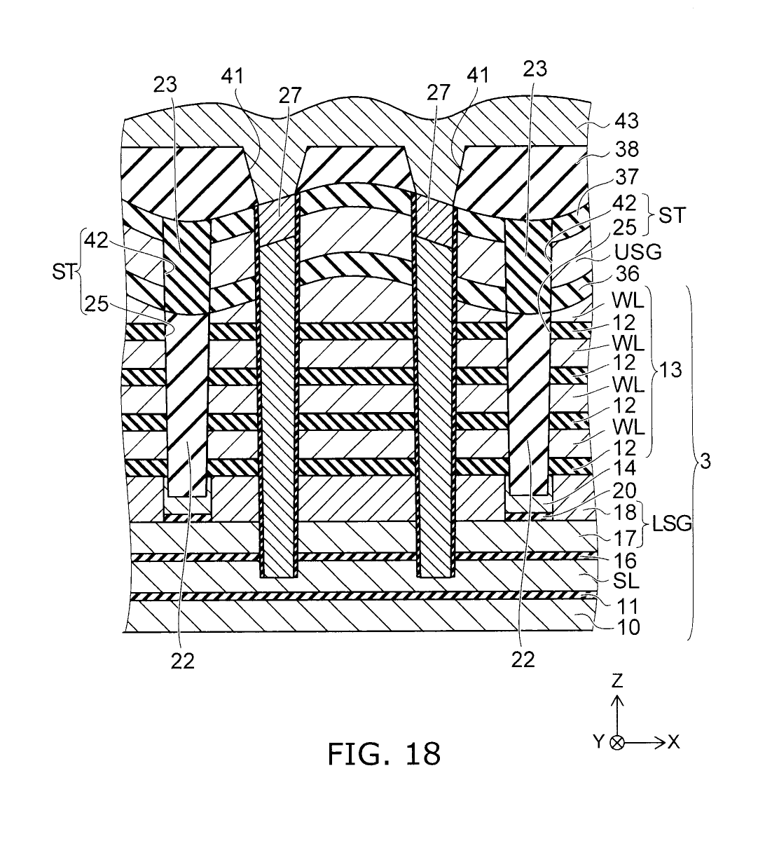

Next, as shown in FIG. 18, on the interlayer insulating film 38 and the electrode 27, e.g., tungsten is deposited to form a conductive film 43. At this time, since a shape of an upper face of the electrode 27 has become an inclined shape in which a direction where the nearest slit ST exists becomes a valley side, a contact face between the conductive film 43 and the electrode 27 also similarly becomes an inclined shape in which a direction where the nearest slit ST exists becomes a valley side. Thereby, a contact area between the conductive film 43 and the electrode 27 becomes large as compared with a case where the conductive film 43 and the electrode 27 come into contact with each other on a plane perpendicular to the central axis of the electrode 27 and the silicon pillar SP.

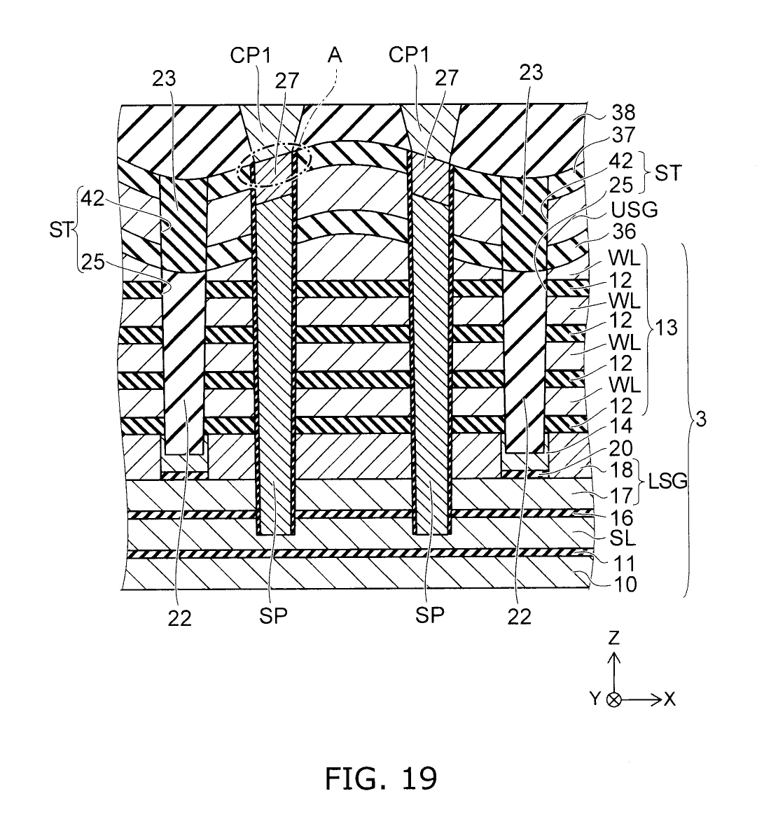

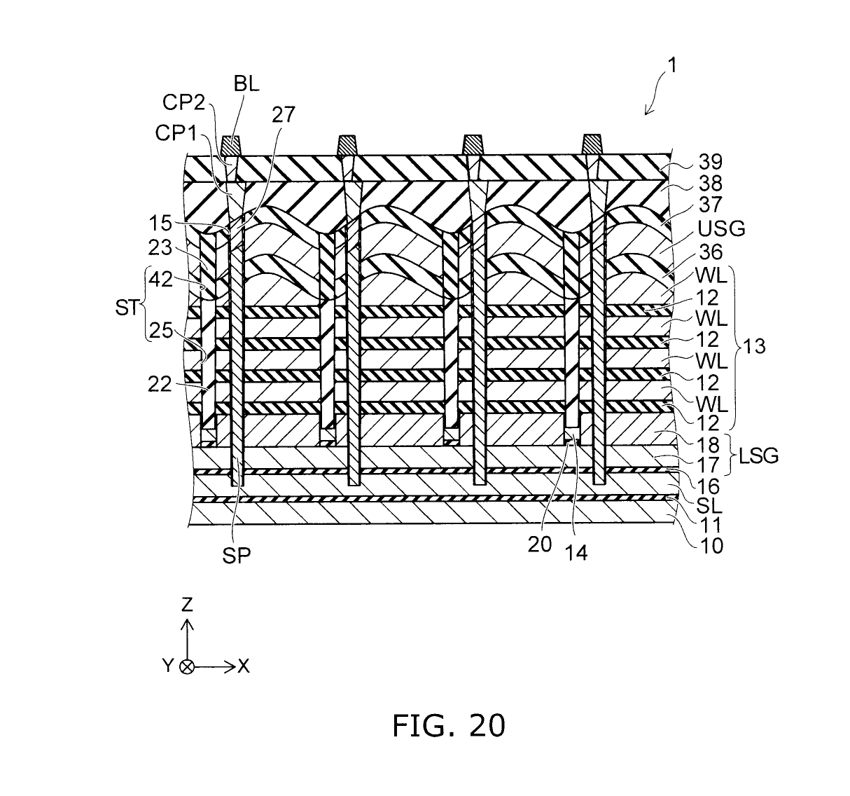

Next, as shown in FIG. 19, by removing by, e.g., the CMP method the conductive film 43 formed on an upper face of the interlayer insulating film 38, the contact plug CP1 is formed in the contact hole 41. As the result, like a portion A shown in FIG. 19, a contact face between the contact plug CP1 and the electrode 27 becomes an inclined shape in which a direction where the nearest slit ST exists becomes a valley side. Because the contact face has become inclined, a contact area between the contact plug CP1 and the electrode 27 becomes large as compared with a case where the contact plug CP1 and the electrode 27 come into contact with each other on a plane perpendicular to the central axis of the electrode 27 and the contact plug CP1.

Next, as shown in FIG. 1, in the same way as formation of the contact plug CP1, the contact plug CP2 is formed on the contact plug CP1. Thereafter, on the contact plug CP2, the bit line BL extending in the X-direction is formed by using, e.g., a damascene method. In this way, the integrated circuit device 1 is manufactured.

Next, an effect of the embodiment will be described.

As for the integrated circuit device 1 according to the embodiment, a contact face between the contact plug CP1 and the electrode 27 provided in an upper part of the silicon pillar SP is inclined relative to a plane perpendicular to the central axis of the electrode 27 and the contact plug CP1, and therefore, those contact areas become large as compared with a case where the contact plug CP1 and the electrode 27 come into contact with each other on a plane perpendicular to the central axis of the electrode 27 and the contact plug CP1. As the result, a contact resistance between the contact plug CP1 and the electrode 27 can be made low. In addition, a rate of an open fault due to a contact failure between the contact plug CP1 and the electrode 27 can be decreased.

### Variation of First Embodiment

Next, a variation of the first embodiment will be described.

FIG. 20 is a sectional view illustrating an integrated circuit device according to the variation.

As shown in FIG. 20, the silicon pillar SP is formed between the insulating member 23 and the highest point of the interlayer insulating film 37, which is nearest to the insulating member 23. Thereby, an inclination of the contact face between the electrode 27 and the contact plug CP1 can be aligned in a uniform direction.

Configurations, manufacturing methods, and effects other than the above in the variation are the same as those of the first embodiment mentioned above.

### Second Embodiment

Next, a second embodiment will be described.

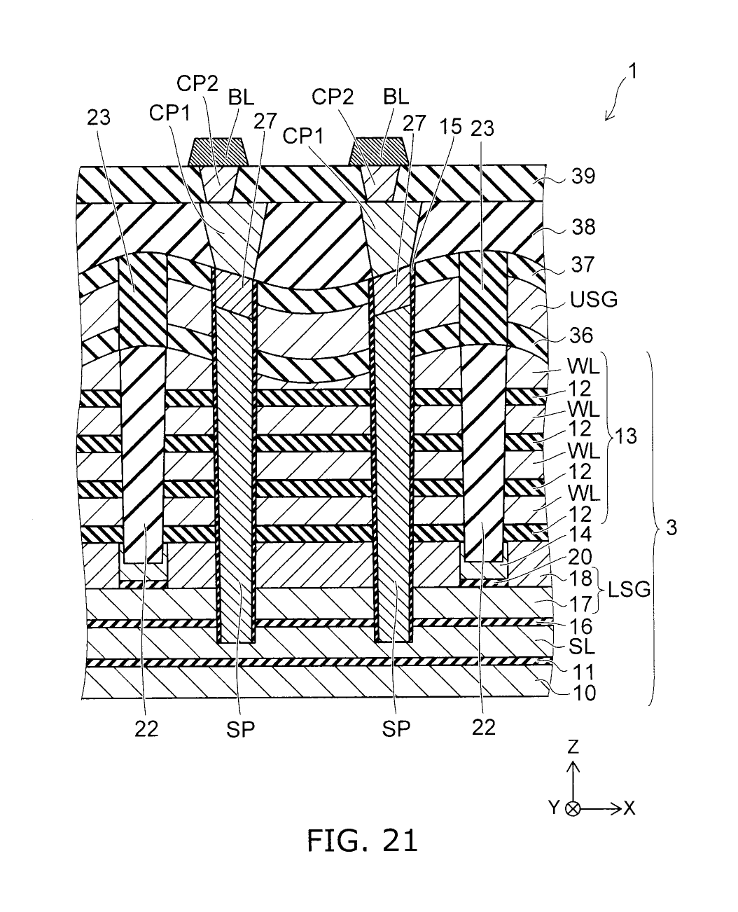

FIG. 21 is a sectional view illustrating an integrated circuit device according to the embodiment.

First, a configuration of the integrated circuit device according to the embodiment will be described.

As shown in FIG. 21, the insulating member 23 is provided at a projecting part higher than the periphery of the interlayer insulating film 37 as compared with the first embodiment mentioned above (refer to FIG. 1). As the result, a contact face between the electrode 27 and the contact plug CP1 becomes an inclined shape in which a direction where the nearest slit ST exists becomes a mountain side.

Configurations other than the above in the embodiment are the same as those of the first embodiment mentioned above.

Next, a method for manufacturing the integrated circuit device according to the embodiment will be described.

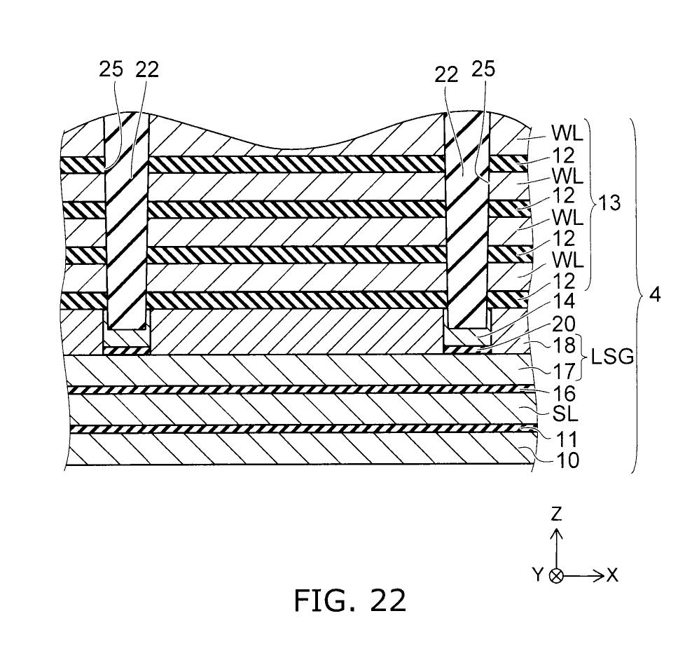

FIGS. 22 to 26 are sectional views illustrating the method for manufacturing the integrated circuit device according to the embodiment.

First, processes until the inside of the lower part 25 of the slit ST is filled up with an insulating material composed of, e.g., a silicon oxide to form the insulating member 22 (refer to FIG. 8) are the same as the processes of the first embodiment mentioned above.

Next, as shown in FIG. 22, overall etching is applied on a condition that an etching rate of silicon becomes higher than an etching rate of a silicon oxide. Thereby, a portion deposited on an upper face of the stacked body 13 in the insulating material is removed. At this time, by applying the over etching, an upper layer portion of the word line WL constituting the top layer of the stacked body 13 and an upper part of the insulating member 22 are also removed. However, in the etching, since an etching rate of silicon is higher than an etching rate of a silicon oxide, the word line WL is preferentially etched rather than the insulating member 22. As the result, on a face including an upper face of the insulating member 22 and an upper face of the word line WL, a wave shape where an upper face of the word line WL becomes relatively lower and an upper face of the insulating member 22 becomes relatively higher appears. An intermediate structure fabricated until this process is assumed to be a structure 4.

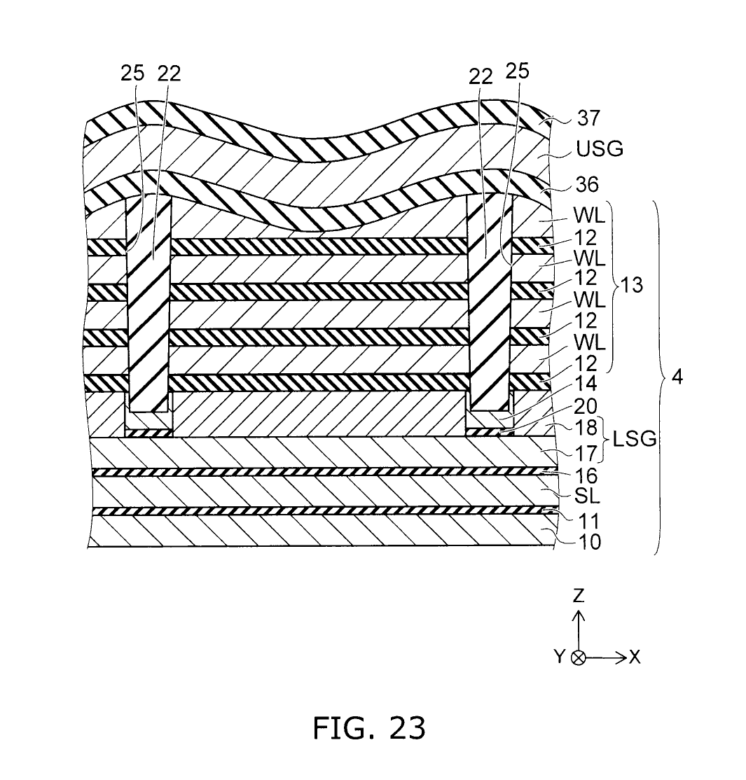

Next, as shown in FIG. 23, the interlayer insulating film 36, the upper selection gate electrode USG and the interlayer insulating film 37 are stacked in this order on the structure 4. At this time, a shape of the interlayer insulating film 36, the upper selection gate electrode USG and the interlayer insulating film 37 becomes a wave shape reflecting a shape of the foundation (refer to FIG. 22).

A formation method from formation of the memory hole MH to formation of the silicon pillar SP is the same as the method for manufacturing the integrated circuit device according to the first embodiment mentioned above.

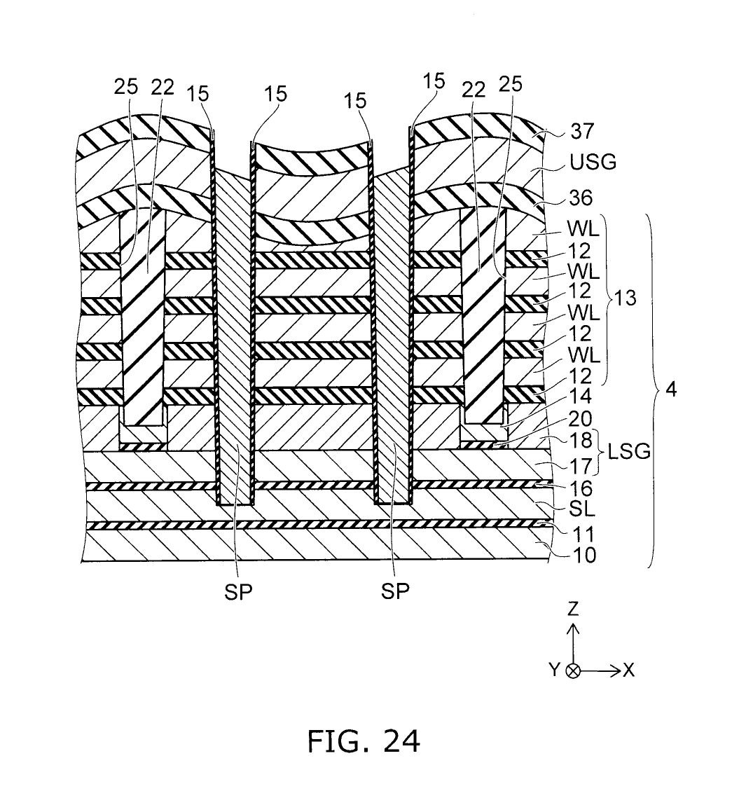

Next, as shown in FIG. 24, an upper part of the silicon pillar SP is removed by applying etchback. At this time, a shape of an upper face of the silicon pillar SP becomes an inclined shape.

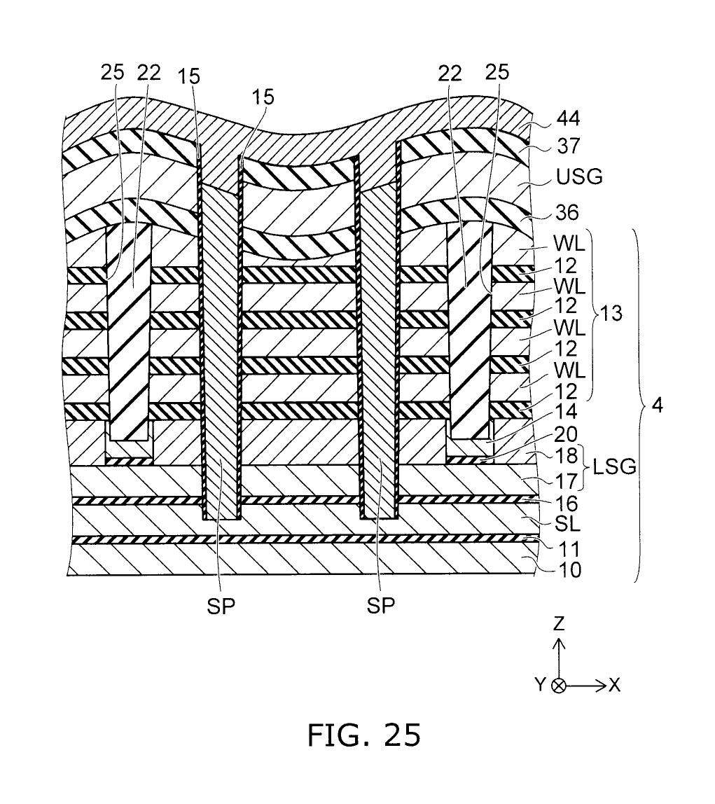

Next, as shown in FIG. 25, on the silicon pillar SP and the interlayer insulating film 37, a conductive member 44 is formed by depositing a conductive material including, e.g., silicon. At this time, a shape of an upper face of the conductive member 44 becomes a wave shape by being influenced by a shape of an upper face of the interlayer insulating film 37.

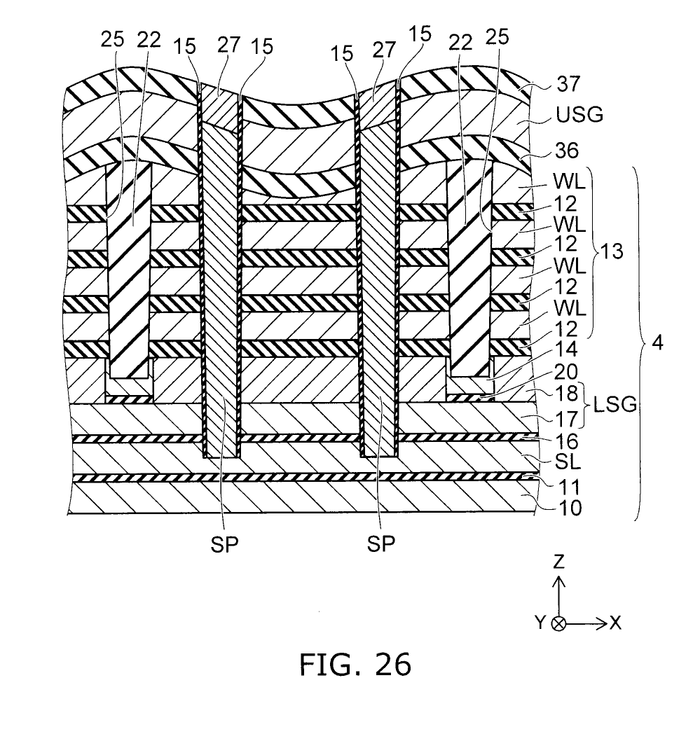

Next, as shown in FIG. 26, other portions except the portion embedded in the memory hole MH of the conductive member 44 are removed by applying etchback on the whole surface. The portion remaining in the memory hole MH is made to be the electrode 27. A shape of an upper face of the electrode 27 becomes an inclined shape in which a side where the nearest slit ST exists becomes a mountain side, by being influenced by a shape of the peripheral interlayer insulating film 37. Thereby, an area of an exposed surface of the electrode 27 becomes large as compared with a case where the exposed surface of the electrode 27 is a plane perpendicular to the central axis of the electrode 27 and the silicon pillar SP.

Manufacturing methods and effects other than the above in the embodiment are the same as those of the first embodiment mentioned above.

### Third Embodiment

Next, a third embodiment will be described.

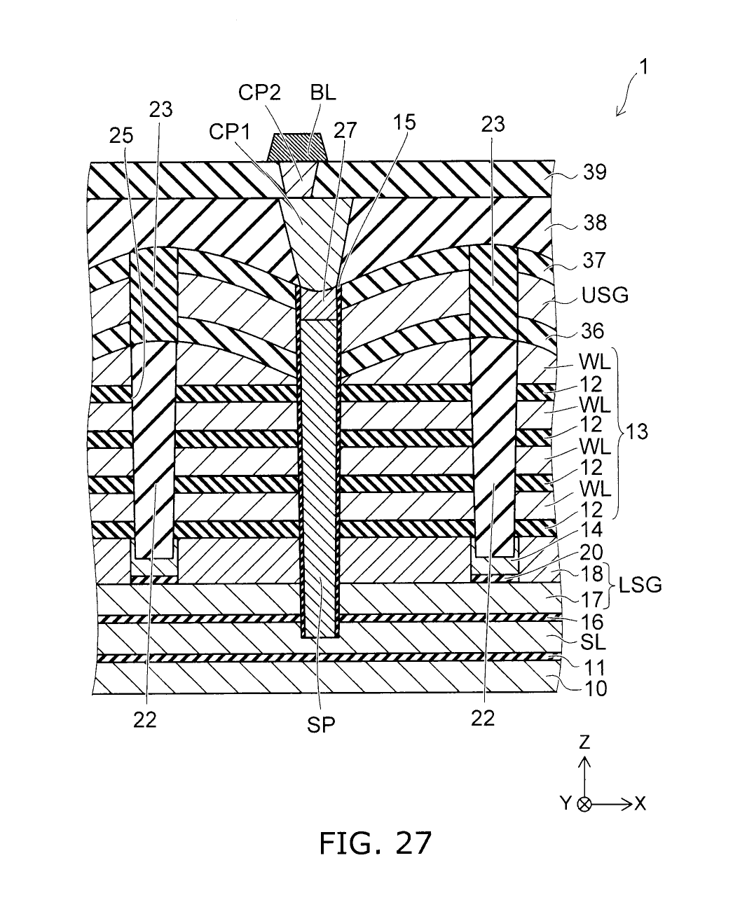

FIG. 27 is a sectional view illustrating an integrated circuit device according to the embodiment.

As shown in FIG. 27, the silicon pillar, the electrode 27 and the contact plug CP1 are provided at a recess part lower than the periphery of the interlayer insulating film 37 as compared with the second embodiment mentioned above (refer to FIG. 21). As the result, a shape of a face of the electrode 27 coming in contact with the contact plug CP1 has become a shape where the central part thereof in the X-direction is recessed.

Configurations other than the above in the embodiment are the same as those of the second embodiment mentioned above.

Next, a method for manufacturing the integrated circuit device according to the embodiment will be described.

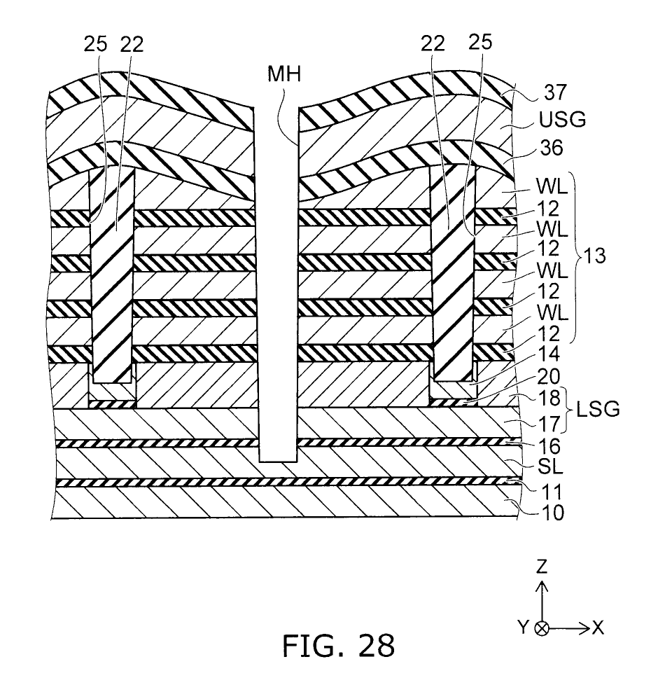

FIGS. 28 to 30 are sectional views illustrating the method for manufacturing the integrated circuit device according to the embodiment.

First, processes until the interlayer insulating film 36, the upper selection gate electrode USG and the interlayer insulating film 37 are stacked in this order on the stacked body 13 and the slit ST are the same as the processes of the second embodiment mentioned above (refer to FIG. 23).

Next, as shown in FIG. 28, the memory hole MH penetrating a stacked body from the interlayer insulating film 37 to an upper layer portion of the source line SL in the Z-direction is formed at a position of a recess part lower than the periphery of the interlayer insulating film 37. Thereafter, a formation method until the silicon pillar SP is formed is the same as the method for manufacturing the integrated circuit device according to the second embodiment mentioned above.

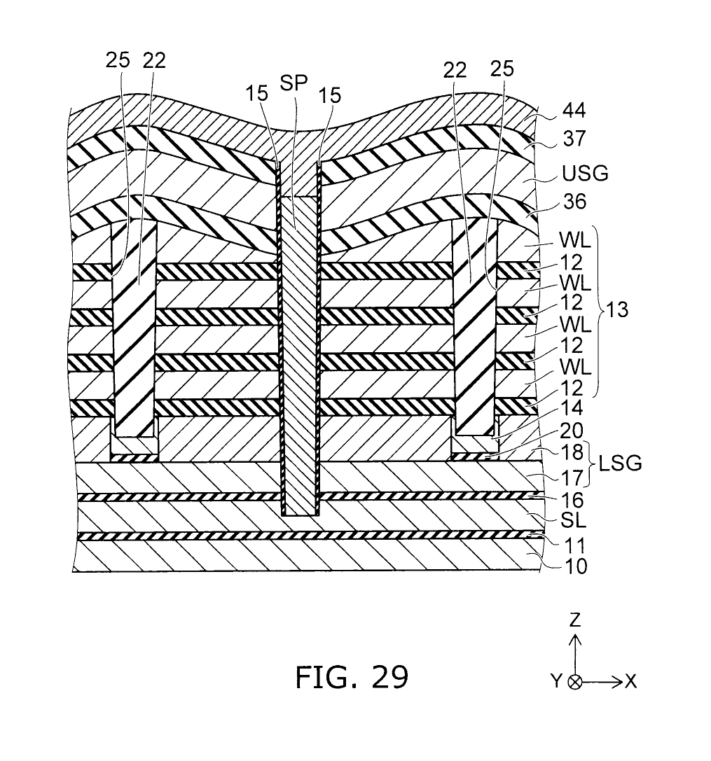

Next, as shown in FIG. 29, an upper part of the silicon pillar SP is removed by applying etchback. Thereafter, on the silicon pillar SP and the interlayer insulating film 37, the conductive member 44 is formed by depositing a conductive material including, e.g., silicon. At this time, a shape of an upper face of the conductive member 44 becomes a wave shape by being influenced by a shape of an upper face of the interlayer insulating film 37.

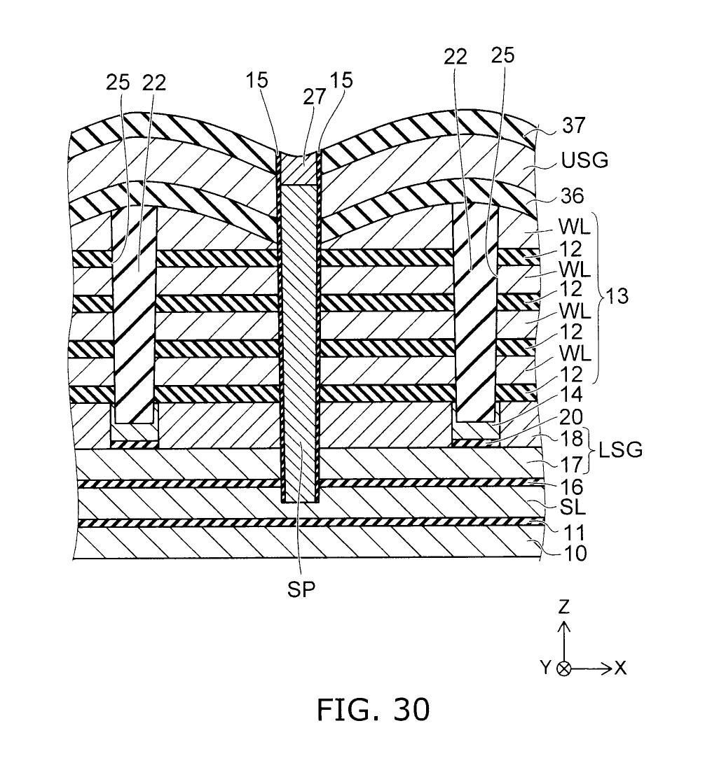

Next, as shown in FIG. 30, other portions except the portion embedded in the memory hole MH of the conductive member 44 are removed by applying etchback on the whole surface. The portion remaining in the memory hole MH is made to be the electrode 27. A shape of an upper face of the electrode 27 becomes a shape where the central part thereof in the X-direction is recessed. Thereby, an area of an exposed surface of the electrode 27 becomes large as compared with a case where the exposed surface of the electrode 27 is a plane perpendicular to the central axis of the electrode 27 and the silicon pillar SP.

Manufacturing methods and effects other than the above in the embodiment are the same as those of the second embodiment mentioned above.

### Fourth Embodiment

Next, a fourth embodiment will be described.

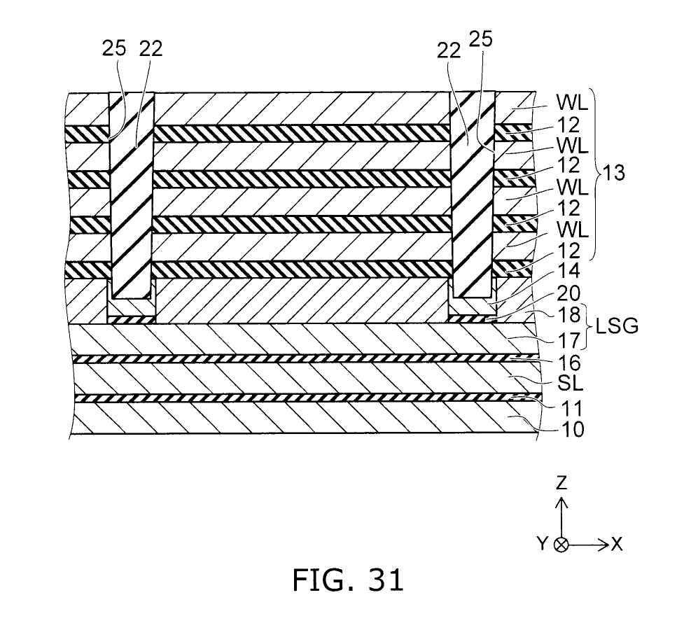

FIGS. 31 to 34 are sectional views illustrating a method for manufacturing an integrated circuit device according to the embodiment.

As for the integrated circuit device according to the embodiment, the manufacturing method differs as compared with the integrated circuit device according to the third embodiment mentioned above. Hereinafter, the manufacturing method will be described.

First, a formation method until the insulating member 22 (refer to FIG. 8) is formed is the same as the formation method of the third embodiment mentioned above.

Next, as shown in FIG. 31, other portions except the portion embedded in the lower part 25 of the slit ST of the insulating member 22 are removed by applying etchback. Thereafter, flattening treatment is carried out to expose the insulating member 22 and the stacked body 13.

A formation method from formation of the interlayer insulating film 36 to formation of the silicon pillar SP is the same as the method for manufacturing the integrated circuit device according to the third embodiment mentioned above.

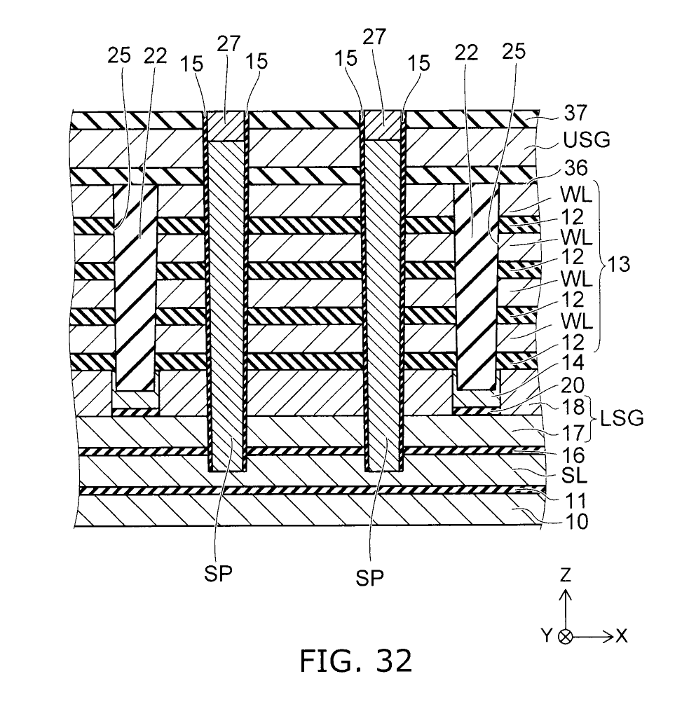

Next, as shown in FIG. 32, after an upper part of the silicon pillar SP is removed by applying etchback, the conductive member 44 is formed by depositing a conductive material including, e.g., silicon. Thereafter, other portions except the portion embedded in the memory hole MH of the conductive member 44 are removed by applying etchback on the whole surface. The portion remaining in the memory hole MH is made to be the electrode 27.

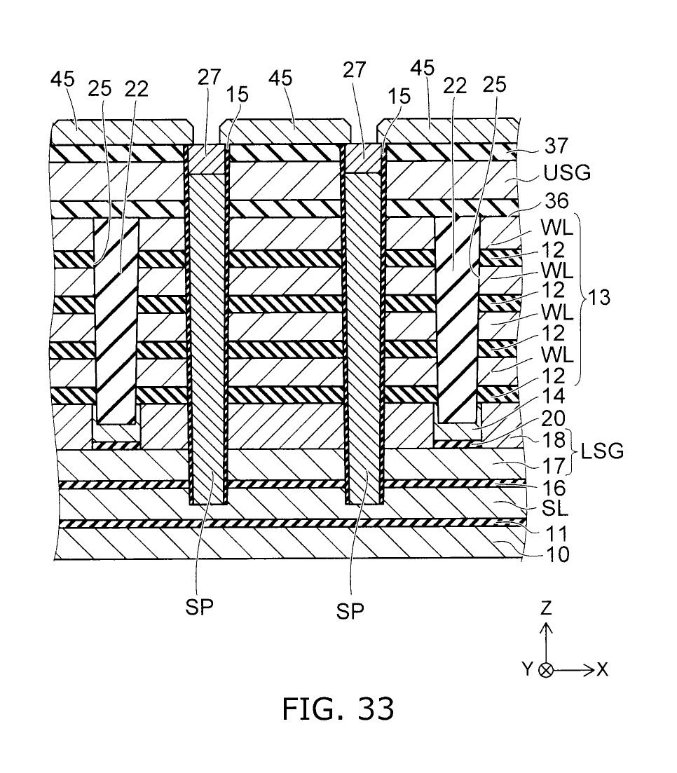

Next, as shown in FIG. 33, on an upper face of the electrode 27 and the interlayer insulating film 37, an X-direction central part of an upper face of the electrode 27 is made to be exposed and a resist 45 is provided on the other portions to specify a region where a recess part is formed.

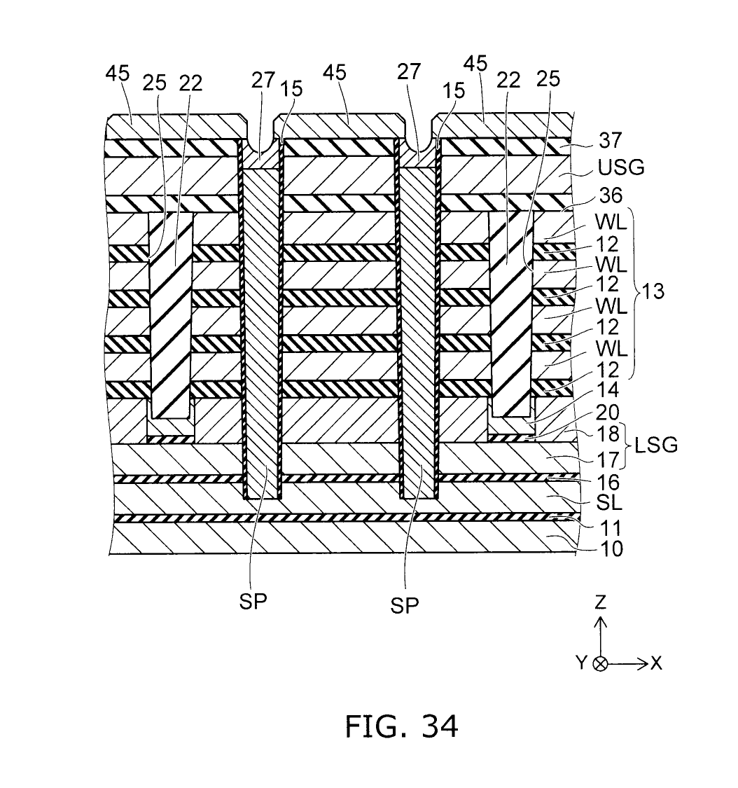

Next, as shown in FIG. 34, etching is applied. This etching is performed on a portion where the resist 45 is not provided, that is, the X-direction central part of an upper face of the electrode 27. As the result, a shape of an upper face of the electrode 27 becomes a shape where the X-direction central part is recessed rather than the periphery. Thereby, an area of the exposed surface of the electrode 27 becomes large as compared with a case where the exposed surface of the electrode 27 is a flat face.

Manufacturing methods other than the above in the embodiment are the same as those of the third embodiment mentioned above.

### Variation of Fourth Embodiment

Next, a variation of a fourth embodiment will be described.

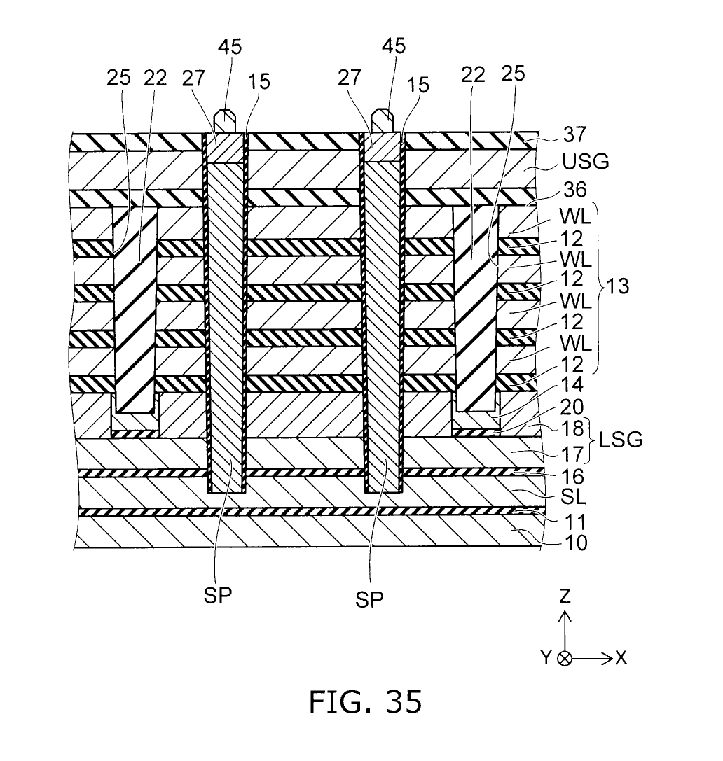

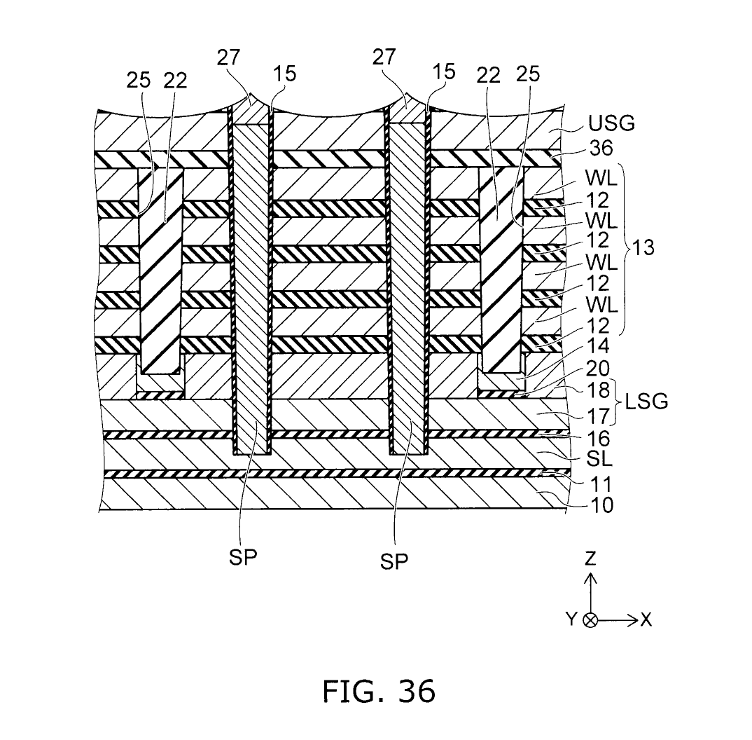

FIGS. 35 and 36 are sectional views illustrating a method for manufacturing an integrated circuit device according to the variation.

First, a formation method until the electrode 27 (refer to FIG. 32) is formed is the same as the formation method of the fourth embodiment mentioned above.

Next, as shown in FIG. 35, the resist 45 is provided on a X-direction central part of an upper face of the electrode 27 to specify a region where a projecting part is formed.

Next, as shown in FIG. 36, etching is applied on the whole surface. Since the resist 45 exists on the X-direction central part of an upper face of the electrode 27, etching is applied on the other faces. By applying etching, portions except the X-direction central part of the electrode 27 and an upper face of the interlayer insulating film 37 are removed. Because the X-direction central part of the electrode 27 remains, the X-direction central part of the electrode 27 becomes a shape which is swollen rather than the periphery thereof. As the result, an area of the exposed surface of the electrode 27 becomes large as compared with a case where the exposed surface is a flat face.

Configurations, manufacturing methods, and effects other than the above in the variation are the same as those of the fourth embodiment mentioned above.

According to embodiments described above, a contact area between an electrode and a contact plug is enlarged, and thereby, an integrated circuit device where a contact resistance is made low and a manufacturing method thereof can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An integrated circuit device, comprising:
a pillar extending in a first direction;
a plug that is connected to an end part of the pillar on a longitudinal direction side,
a contact face between the pillar and the plug including a portion inclined relative to a plane perpendicular to the first direction.

2. The device according to claim 1, further comprising:
a substrate;
a stacked body which is provided on the substrate, and in which an insulating film and an electrode film are stacked alternately;
a wiring provided on the stacked body; and
a memory film which is provided around the pillar, and is capable of storing an electric charge, wherein
the pillar is composed of a semiconductor material,
the pillar penetrates the stacked body, and
the plug is connected between the pillar and the wiring.

3. The device according to claim 2, further comprising an insulating member which is provided lateral to the pillar and extends in the first direction, wherein the contact face is a slope where a side on which the nearest insulating member exists is close to the substrate.

4. The device according to claim 2, further comprising an insulating member which is provided lateral to the pillar and extends in the first direction, wherein the contact face is a slope where a side on which the nearest insulating member exists is far from the substrate.

5. The device according to claim 1, further comprising an electrode that is connected between an end part of the pillar on the first direction side and the plug, wherein a shape of an end part of the electrode on the first direction side is a shape in which a central part in a direction perpendicular to the first direction is recessed.

6. The device according to claim 1, further comprising an electrode that is connected between an end part of the pillar on the first direction side and the plug, wherein a shape of an end part of the electrode on the first direction side is a shape in which a central part in a direction perpendicular to the first direction is swollen.

7. The device according to claim 5, wherein the electrode contains silicon, a metal silicide or a metal.

8. A method for manufacturing an integrated circuit device, comprising:
forming a stacked body on a substrate by stacking an insulating film and an electrode film alternately;
forming a slit penetrating the stacked body in the stacking direction to form an insulating member by embedding an insulating material into the slit;
removing an upper part of the insulating member and the stacked body to form a first wave shape on a face including an upper face of the insulating member and an upper face of the stacked body;
forming a memory hole penetrating the stacked body in the stacking direction;
depositing a semiconductor material in the memory hole to form a semiconductor member;
depositing a conductive material on the semiconductor member, the insulating member and the stacked body to form a conductive member, and forming a second wave shape reflecting the first wave shape on an upper face of the conductive member; and
forming an electrode by removing the conductive member except in the memory hole to form a semiconductor pillar composed of the semiconductor member and the electrode, and forming a third wave shape reflecting the second wave shape on a face including an upper face of the insulating member, an upper face of the semiconductor pillar and an upper face of the stacked body,
the semiconductor pillar upper face including a part of the third wave shape.

9. The method according to claim 8, wherein in forming the first wave shape, an upper face of the insulating member is set to be relatively low, and an upper face of the stacked body is set to be relatively high.

10. The method according to claim 8, wherein in forming the first wave shape, an upper face of the insulating member is set to be relatively high, and an upper face of the stacked body is set to be relatively low.

11. The method according to claim 8, wherein the electrode contains silicon, a metal silicide or a metal.

12. A method for manufacturing an integrated circuit device, comprising:
forming a stacked body on a substrate by stacking an insulating film and an electrode film alternately;
forming a slit penetrating the stacked body in the stacking direction to form an insulating member by embedding an insulating material into the slit;
forming a memory hole penetrating the stacked body in the stacking direction;
depositing a semiconductor material in the memory hole to form a semiconductor pillar;
providing a resist on a part of an upper face of the semiconductor pillar; and
applying etching on a face including an upper face of the resist and an upper face of the semiconductor pillar.

13. The method according to claim 12, wherein the part includes both end portions of an upper face of the semiconductor pillar in a direction perpendicular to the stacking direction.

14. The method according to claim 12, wherein the part includes a central part of an upper face of the semiconductor pillar in a direction perpendicular to the stacking direction.
